(19) United States
(12) Patent Application Publication
(10) Pub. No.: US 2025/0176351 A1
(43) Pub. Date: May 29, 2025

(54) ORTHORHOMBIC CSPBI3 MICROWIRES FOR SENSITIVE FLEXIBLE HIGH-RESOLUTION X-RAY DETECTORS

(71) Applicant: UVic Industry Partnerships Inc., Victoria (CA)

(72) Inventors: Soumya Kundu, Victoria, BC (CA); Makhsud Saidaminov, Victoria, BC (CA)

(73) Assignee: UVic Industry Partnerships Inc., Victoria, BC (CA)

(21) Appl. No.: 18/839,338

(22) PCT Filed: Feb. 17, 2023
(86) PCT No.: PCT/IB2023/051478

§ 371 Date: Aug. 16, 2024

Related U.S. Application Data
(60) Provisional application No. 63/268,193, filed on Feb. 17, 2022.

(51) Int. Cl. H10K 39/36; C30B 7/06; C30B 21/02; C30B 29/12; G01T 1/24; H10K 71/12

(52) U.S. Cl. CPC H10K 39/36; C30B 7/06; C30B 21/02; C30B 29/12; G01T 1/24; H10K 71/12

(57) ABSTRACT

X-ray detectors are made by growing CsPbI₃ on a treated surface of a conductive layer. Growth is controlled by increasing solvent concentration in the atmosphere in which the growth occurs. Columnar crystals grown in a plurality of wells extend between conductive surfaces at least one of which is pixelated to produce a columnar detector array.

### CROSS REFERENCE TO RELATED APPLICATION

This application claims the benefit of U.S. Provisional Patent Application 63/268,193, filed Feb. 17, 2022, which is incorporated herein by reference.

### FIELD

The disclosure pertains to X-ray detectors.

### BACKGROUND

X-ray detectors are used for a wide range of applications including biomedical imaging, industrial monitoring, security screening, and scientific research. Direct conversion X-ray detectors directly convert X-ray photons into an electrical signal, while indirect conversion detectors (also called scintillators) first convert X-ray photons to visible light. Subsequently, this light is converted to an electrical signal using visible light detectors. Direct conversion detectors are simpler in configuration and offer higher spatial resolution than scintillators.

Among traditional semiconductors, amorphous selenium (a-Se) and Cd₁₋ₓZnₓTe (CZT, x<20%)-based materials dominate the market of commercial X-ray detectors. a-Se has a low device dark current and stable device performance; however, it possesses low X-ray absorptivity. On the other hand, CZT offers excellent absorptivity, but requires high temperature processing conditions (>900° C.) and suffers from structural imperfections and compositional inhomogeneity. Additionally, these materials suffer from low carrier mobility-lifetime product (μτ), which is a fundamental figure-of-merit for an X-ray absorber determining charge collection efficiency. A summary of detector characteristics of conventional detectors and the disclosed detector can be found in the table in FIG. 21. These limitations demand the development of novel semiconductors for direct X-ray detectors.

Solution-processed metal halide perovskites have recently emerged as a family of unique semiconductors for X-ray detectors. Due to their elemental constitution of heavy atoms such as lead and iodine, metal halide perovskites have a high X-ray attenuation coefficient. However, conventional perovskites suffer from long-term instability, high dark current (which determines noise levels), and moderate μτ products.

Early diagnosis of diseases requires high spatial resolution, which is measured by recording the resolving power of a line-pair phantom. For radiology, a minimum spatial resolution of 5.7 lp mm⁻¹ is required for adequate resolution of small objects. Imaging becomes more challenging when it comes to mammographic applications, where a resolution of 10 lp mm⁻¹ is needed to resolve small microcalcifications. Unfortunately, conventional detectors do not lend themselves to high-resolution X-ray imaging, as they are integrated into transistor arrays with limited pixel dimensions.

For these and other reasons, alternative X-ray detection materials, methods, and devices are needed.

### SUMMARY

Methods of growing orthorhombic cesium lead iodide (δ-CsPbI3) microwires comprise drop-casting a solution of CsI and PbI₂ in a solvent onto a patterned substrate and forming at least one δ-CsPbI3 microwire by allowing the solvent to evaporate. In some examples, the patterned substrate is situated in a solvent-rich atmosphere to control evaporation rate.

X-ray detectors comprise a first conductor and a second conductor and at least one orthorhombic cesium lead iodide (δ-CsPbI₃) microwire extending from the first conductor to the second conductor and electrically coupled to the first conductor and the second conductor. In some examples, the conductor is ITO or gold situated on a rigid or flexible substrate.

In other examples, X-ray detectors comprise a base substrate, an upper substrate, and plurality of δ-CsPbI₃ microwires extending from the base substrate to the upper substrate. The base substrate typically includes a base conductive layer and the upper substrate typically includes an upper conductive layer, wherein each of the plurality of δ-CsPbI₃ microwires extends from the base conductive layer to the upper conductive layer. In some examples, at least one of the conductive layers is pixelated.

Other representative methods comprise growing δ-CsPbI₃ microwires in a plurality of wells so that a first end of each extends to a base conductive layer and contacting second ends of each of the δ-CsPbI₃ microwires to an upper conductive layer. In some examples, a mold layer is formed on the base conductive layer and a defines wells that extend to the base conductive layer, wherein the δ-CsPbI₃ microwires are grown in the wells.

The foregoing and other features and advantages will become more apparent from the following detailed description, which proceeds with reference to the accompanying figures.

### BRIEF DESCRIPTION OF THE DRAWINGS

FIG. 1 illustrates a representative method of making an X-ray detector crystal.

FIG. 1A illustrates a representative X-ray detector based on an X-ray detector crystal made by the method such as shown in FIG. 1.

FIG. 2A illustrates crystallization on a hydrophobic surface.

FIGS. 2B-2C shows crystallization on treated surface with a rectangular mask and a triangular mask, respectively.

FIG. 2D is a dark field image of crystals produced on a treated surface by optical microscopy FIG. 2E is a high-resolution SEM image of δ-CsPbI₃ crystals such formed on a treated surface.

FIG. 2F is an X-ray diffraction (XRD) analysis of simulated and as-grown δ-CsPbI₃ single crystals.

FIG. 2G illustrates δ-CsPbI₃ crystal structure. The crystal grows along [100] axis which is almost perpendicular to (111) and (211) planes, explaining their resonance peaks on XRD.

FIGS. 3A-3B illustrate contact angles before and after hydrophilization, respectively.

FIG. 4A illustrates different mask designs that define surface areas for hydrophilization to facilitate directional crystallization.

FIG. 4B illustrates single crystal growth from the mask designs of FIG. 4A.

FIG. 5 illustrates δ-CsPbI₃ single crystals grown from triangular mask designs with varying angles.

FIG. 6 illustrates the effects of changing the concentration of precursor solution on δ-CsPbI₃ crystal growth.

FIG. 7 illustrates directional growth of δ-CsPbI₃ microwires using DMF and DMSO.

FIG. 8 contains SEM images of δ-CsPbI₃ single crystals grown from DMF and DMSO solutions.

FIG. 9 illustrates an arrangement for DMF-assisted slow evaporation crystallization.

FIG. 10 shows crystallization on a 25 mm by 76 mm substrate.

FIGS. 11A-11D contain SEM images of δ-CsPbI₃ single crystals grown using DMF as solvent at different parts of the crystals. FIGS. 11A-11C are images at a starting point of the crystallization and FIG. 11D is an image at a part of the crystal more distant from the corner.

FIGS. 12A-12B contain EDS data and SEM images associated with a crystal starting point (FIG. 12A) and a microwire (FIG. 12B).

FIGS. 13A-13C illustrate vial-based crystallization at room temperature by a slow evaporation method. FIG. 13B illustrates as-grown δ-CsPbI₃ single crystals in a vial. FIG. 13C shows comparative crystallization on an ITO substrate indicating different region of crystal growth.

FIG. 13D contains measured and simulated powder X-ray diffraction (pXRD) data for a crystal starting point and a middle section. The starting point corresponds to CsI and Cs₄PbI₆ and a middle region is mostly δ-CsPbI₃.

FIGS. 14A-14D contain EDS data and SEM images from a crystal growth starting point (FIG. 14A) to a microwire (FIG. 14D).

FIG. 15A is a schematic representation of a δ-CsPbI₃-based X-ray detector.

FIG. 15B illustrates ON/OFF photocurrent response of the detector under various dose rates.

FIG. 15C shows X-ray generated photocurrent as a function of X-ray dose rate.

FIG. 15D illustrates photoconductivity measurement as a function of X-ray energy.

FIG. 15E illustrates signal-to-noise ratio of the device derived by calculating the standard deviation of the X-ray photocurrent. The shaded area represents a signal-to-noise ratio (SNR)<3. The detection limit is thus calculated to be 33.3 nGyₐᵢᵣ s⁻¹.

FIG. 15F illustrates ON/OFF response of the device to the lowest detectable X-ray dose rate at 125 V mm⁻¹. The data were smoothed by averaging 10 consecutive data points.

FIG. 15G illustrates operational stability of different detectors under continuous exposure to 100 kVp X-rays (45 Gy s⁻¹ dose rate) at an applied bias of 5 V: ITO/δ-CsPbI₃/ITO (line 1510), ITO/MAPbBr₃/ITO (line 1511), and Au/δ-CsPbI₃/Au (line 1512).

FIG. 16A shows dark current as a function of time for a representative δ-CsPbI₃ X-ray detector.

FIG. 16B is a photograph of a representative X-ray detector.

FIG. 17A illustrates a representative columnar δ-CsPbI₃ X-ray detector.

FIGS. 17B-17C illustrate fabrication of the detector of FIG. 17A.

FIG. 18 illustrates a representative method of making columnar δ-CsPbI₃ X-ray detectors.

FIGS. 19A-19B illustrate fabrication of a columnar δ-CsPbI₃ X-ray detectors.

FIG. 19C is a graph showing an ON/OFF ratio of a columnar δ-CsPbI₃ detector (ITO/δ-CsPbI₃/Au) under 50 kVp and 100 kVp X-ray beam energies.

FIGS. 20A-20B are photographs of a representative single pixel device showing the channel and the single CsPbI₃ crystals.

FIGS. 20C-20D are edge spread function (ESFs) associate with laser beam and X-ray exposure of the detector of FIGS. 20A-20B.

FIG. 20E is a graph of MTF for the detector of FIGS. 20A-20B.

FIG. 20F contains an optical image (upper) and an X-ray image (lower) taken with the detector of FIGS. 20A-20B.

FIG. 21 is a table of X-ray detector characteristics.

### DETAILED DESCRIPTION

### Introduction

Disclosed herein are X-ray detectors, devices, and methods that can address deficiencies of conventional devices. In typical examples, aligned orthorhombic δ-CsPbI₃ microwires as disclosed can provide high X-ray absorption coefficients. The monocrystalline nature of this material accounts can provide a product u of 7×10⁻² cm² V⁻¹, the highest recorded among metal halides. The crystals can show a record-low dark current of 412.5 fA mm⁻² under −3,750 V mm⁻¹ electric field, enabled by a record-high bulk resistivity of 2.3×10¹⁴ Ωcm. A Schottky junction with δ-CsPbI₃ is able to sense dose rates as low as 33.3 nGyₐᵢᵣ s⁻¹. An X-ray spatial resolution of ˜12.4 lp mm⁻¹ can be achieved, which is one of the highest values reported to date. Fabricated devices encompassing δ-CsPbI₃ microwires show a long-term operational stability to 100 kVp X-rays with an accumulated total dose of 1.44×10⁶ Gy. The devices are also immune to high relative humidity (RH) of 99% and high temperatures of 100° C. (50-60% RH) for at least 250 hours. Vertically grown δ-CsPbI₃ microwires can provide on/off ratios of at least 1000. These and other examples are discussed below.

As noted above, the performance of an X-ray detector depends on the ability of its semiconductor to absorb X-ray photons efficiently. Absorption of X-rays changes with the effective atomic number (Z_{eff}), by approximately ρZ⁴_{eff}/AE³, where ρ is the density, A is the atomic mass, and E is the X-ray photon energy. Among all lead halide-based ternary compounds, CsPbI₃ has the highest Z_{eff} value of 59.2. The linear attenuation coefficient of CsPbI₃ is higher than that of conventional X-ray sensing materials such as CdTe and Se, as well as lead halide-based materials. CsPbI₃ exists in two polymorphs: orthorhombic (δ-CsPbI₃) and a cubic (or perovskite phase). The perovskite phase is required for applications in solar cells and light-emitting diodes; however, its stabilization at room temperature is challenging as the thermodynamic transition from orthorhombic to cubic phase occurs at ˜320° C. No perovskite phase appears to be mandatory for X-ray detection applications, as long as the material absorbs high-energy photons and transports generated carriers well. Hence, this disclosure emphasizes growth of orthorhombic δ-CsPbI₃. In addition, the orthorhombic phase has a higher density (5.38 g cm⁻³) than the cubic phase (4.81 g cm⁻³), thus absorbing X-rays more effectively than cubic CsPbI₃.

### Directional Crystal Growth of δ-CsPbI₃ Microwires

Conventionally, stand-alone single crystals are grown in a vial and then transferred to a substrate to build a device. Extra care must be taken while handling these fragile crystals to avoid contamination and damage during transfer from a precursor solution. As disclosed herein, crystals can be grown directly on a conductive substrate to devise a Schottky junction for use in a detector, an architecture typically employed in well-performing detectors as described in Saidaminov et al., “Planar-integrated single-crystalline perovskite photodetectors,” Nat. Commun. 6, 8724 (2015). and Quan et al., “Nanowires for Photonics,” Chem. Rev. 119, 9153-9169 (2019), both of which are incorporated herein by reference.

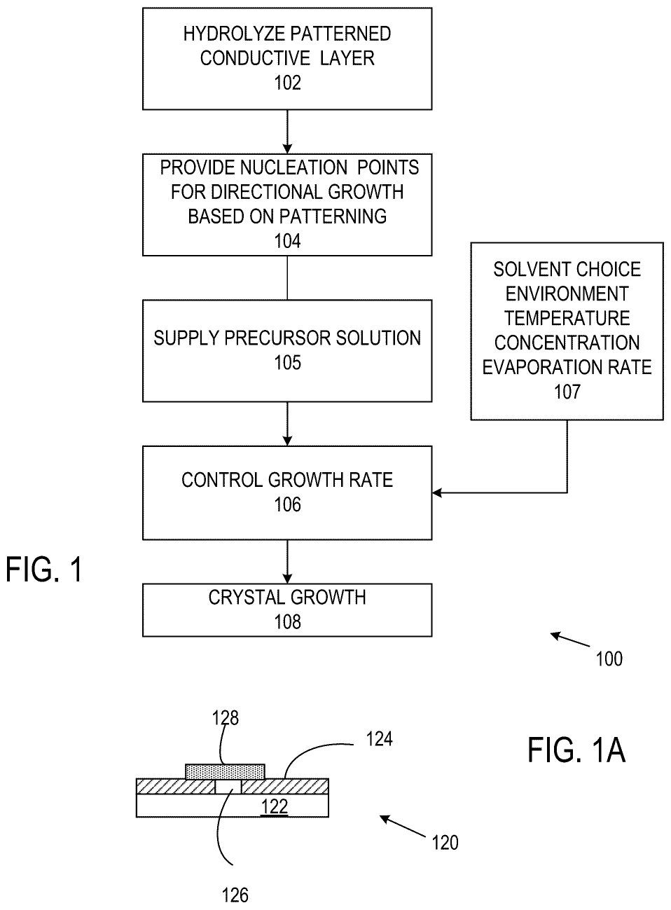

Referring to FIG. 1, a representative method 100 of growing δ-CsPbI₃ single crystals and forming X-ray detectors with these crystals includes hydrolyzing a surface of a patterned conductive layer such as Indium Tin Oxide (ITO) on a rigid or flexible insulating substrate such as glass or plastic at 102. The patterning of the conductive layer is selected to define electrodes of an X-ray detector to be produced. At 104, nucleation points are defined on the conductive layer using masks that provide suitable corners associated with directional crystal growth and at suitable locations with respect to the patterning of the conductive layer. A precursor solution is applied at 105 and solvent evaporation is controlled at 106. Crystal growth is then provided at 108. Examples of these steps are discussed below.

FIG. 1A illustrates a representative arrangement of an X-detector 120 produced with the method of FIG. 1. The X-ray detector 120 includes a substrate 122 in contact with a conductive layer 124 that is patterned to provide a gap 126. A suitable X-ray detector crystal 128 is situated to span the gap 126 so that the conductive layer 124 provides a Schottky barrier and suitable electrical contacts.

### Representative Crystal Growth Example

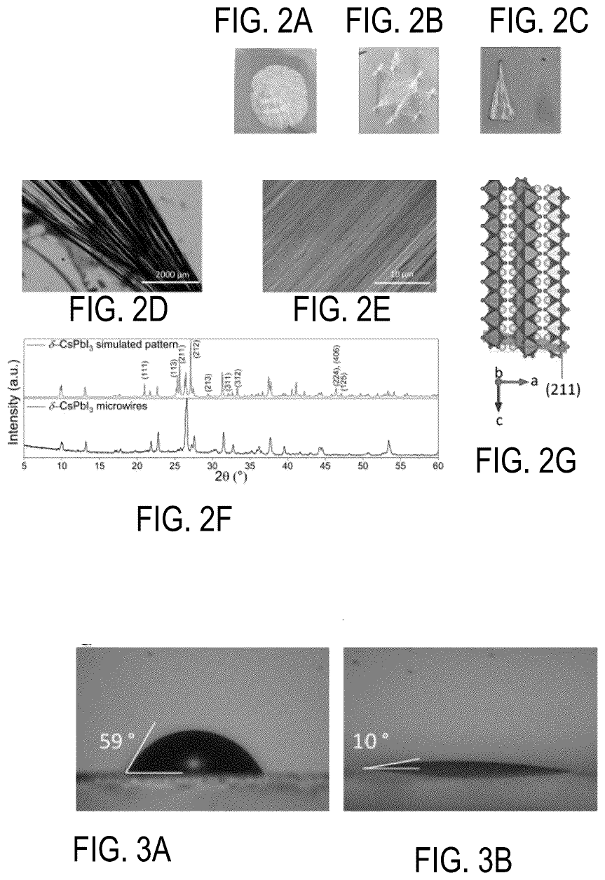

In one approach, δ-CsPbI₃ single crystals were grown directly on 2.5×2.5 cm² ITO substrates with 40 μL of 0.5 M precursor solution of CsI and PbI₂ in N,N-dimethylformamide (DMF) drop-casted and allowed to crystallize by slow evaporation in air. However, this approach generally resulted in small, poor-quality crystals with little directionality as shown in FIG. 2A. To achieve directional growth, an ITO surface was hydrophilized in a rectangular shape. FIGS. 3A-3B show a change in water contact angle from ˜59° before treatment (FIG. 3A) to 10° after hydrophilic treatment (FIG. 3B). This surface treatment made the unmasked area of the substrate hydrophilic, thus improving the adhesion between the single crystal/ITO interface. The untreated, hydrophobic areas of substrate repel liquid and tend to ensure that the solution remains in the treated area. Drop-casting onto the hydrophilic surface led to large and aligned microwires shown in FIG. 2B. Crystallization appears to start at vertices of the rectangle as shown in FIG. 2C. Regulation of evaporation rate can be used to grow well-aligned microwires controllably, as discussed below.

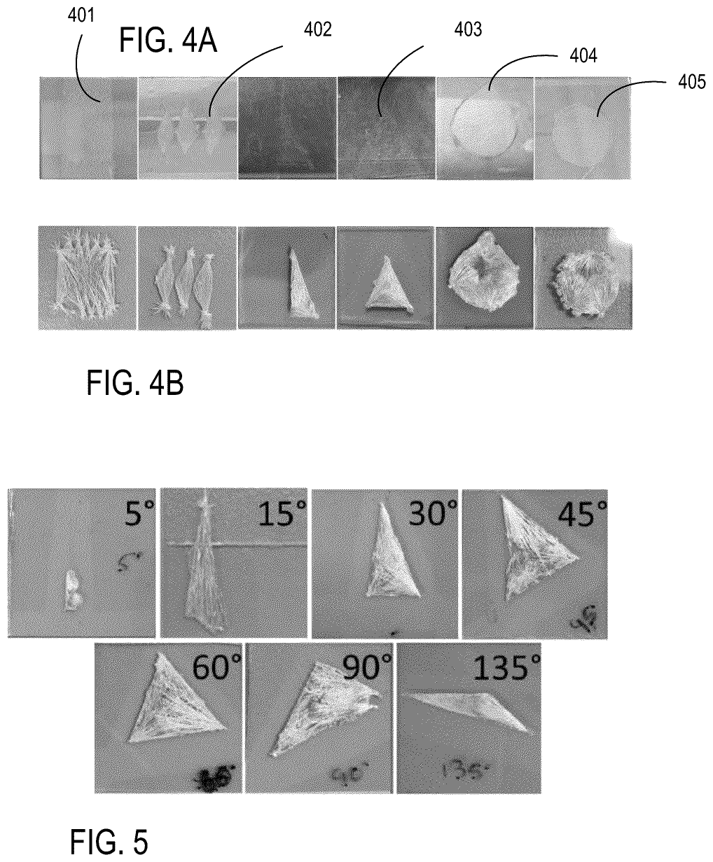

A single nucleation point is indicated for directional growth of δ-CsPbI₃ single crystals. ITO substrates having sharp features where evaporation of solvent was accelerated, and the first nuclei appeared were hydrophilized using various masks to produced corresponding hydrophilic areas 401-405 as shown in FIG. 4A. Crystals were grown by drop casting with corresponding results shown in FIG. 4B. A circular mask, as expected, did not result in directional growth while shapes with corners did. Triangular masks with angles in a range of 5° to 135° were then used, producing crystal growth shown in FIG. 5. Large angles (˜60°) resulted in growth of microwires (i.e., δ-CsPbI₃ crystals) from all vertices of the hydrophilic triangular areas, while an extreme sharp angle of 5° did not lead to proper crystallization, likely due to insufficient precursor material being available at the vertex of the triangular area. Triangles with an acute angle of 15° led to reproducible directional growth of δ-CsPbI₃ microwires.

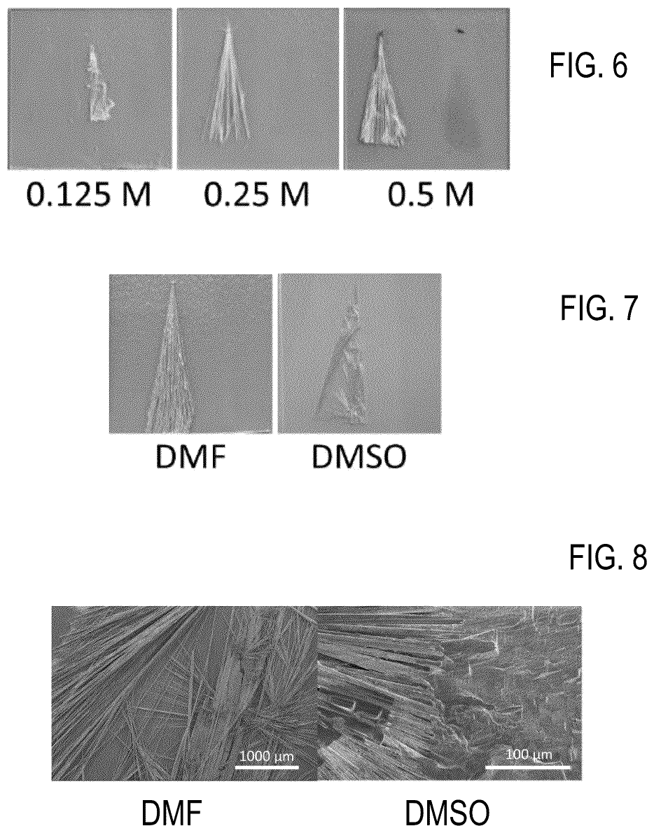

To further improve the quality of crystals, the speed of crystallization was decreased. In one example, the concentration of the precursor solution was decreased, but enough crystals were not formed, likely to due to insufficient amounts of solute. FIG. 6 shows crystal growth obtained with 0.125 M, 0.25 M, and 0.5 M solutions. A different solvent (dimethyl sulfoxide (DMSO)) was also tried as it binds strongly to metal halides and slows down crystallization. This approach generally led to diminished directionality, likely because CsI (2.6 mole L⁻¹ at 20° C.) and PbI₂ (1.0 mole L⁻¹ at 20° C.) have different solubilities in DMSO. In addition, DMSO is less volatile than DMF, therefore taking longer to evaporate which may lead to multiple seeding locations. FIGS. 7-8 illustrate microwire growth with DMF and DMSO, showing that superior results are obtained with DMF.

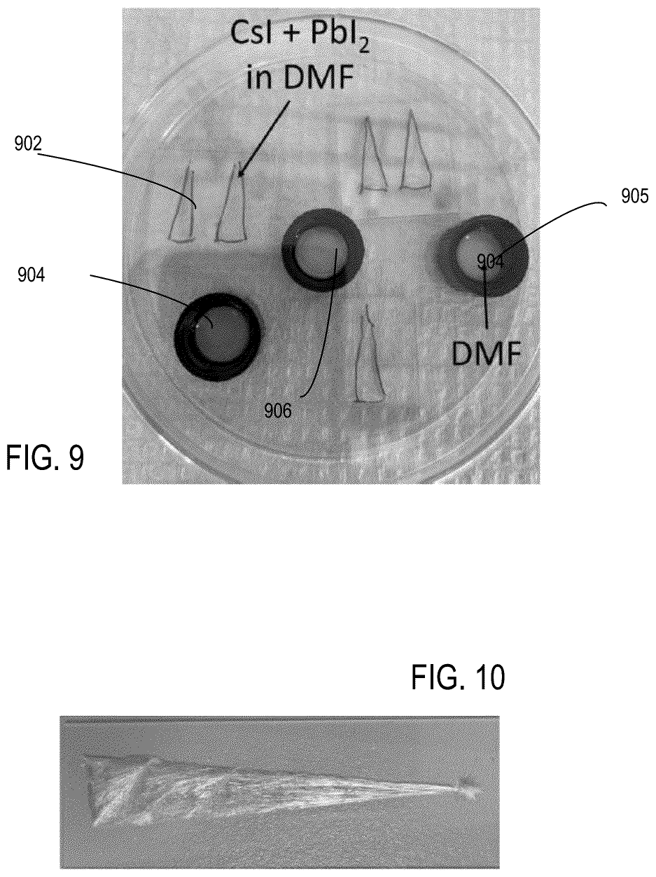

In another approach, a pure solvent vapour was introduced by placing a DMF bath inside a crystallization environment. This resulted in larger, high-quality, unidirectional δ-CsPbI₃ single crystals. As shown in FIG. 9, a solution of CsI/PbI₂ is applied to surface-treated triangular areas such as representative area 902 and solvent wells 904-906 are situated to provide solvent vapour to establish a suitable crystal growth rate; a surrounding container (not shown) is used to provide a solvent-rich atmosphere about the substrate. Representative examples of crystals obtained in this manner are shown in FIG. 2C and FIG. 10. This process can be highly reproducible and cost-effective (for example, only ˜14.4 mg of precursors can be needed to produce high quality cm-long single crystals) and is generally suitable for large-scale production as shown by the 5 cm long unidirectional δ-CsPbI₃ single crystals of FIG. 10. FIG. 2D is a dark field optical microscopy image of δ-CsPbI₃ single crystals grown in this manner, showing 10-100 m diameter microwires. An SEM image (FIG. 2E) shows that the crystals are aligned. The δ-CsPbI₃ single crystals grown on the substrate have preferential orientation in a [100] direction as is evident from the missing peaks on the X-ray diffraction (XRD) patterns (simulated and measured) of FIG. 2F.

### Crystallization Mechanism

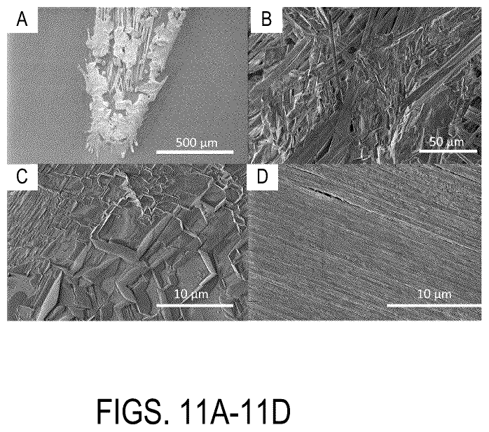

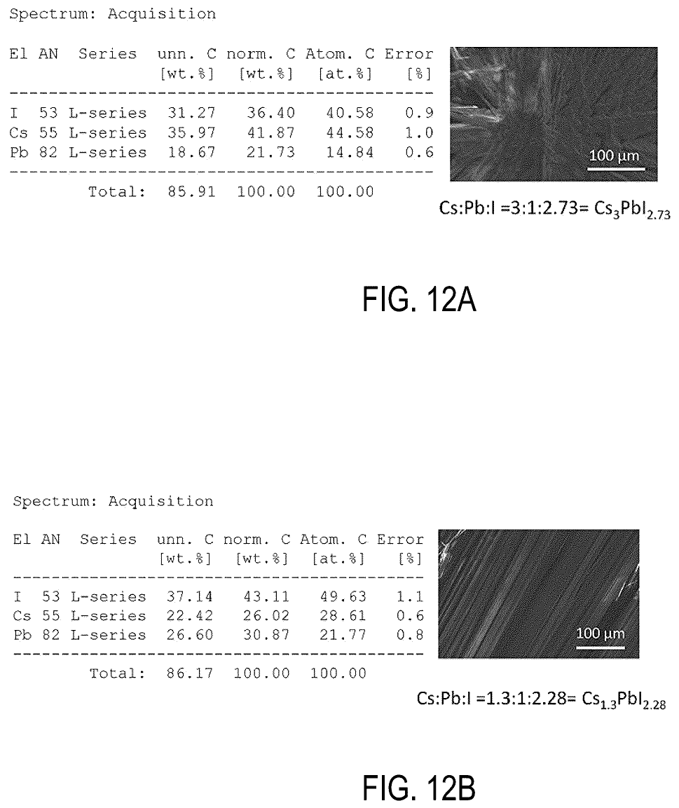

CsI and PbI₂ have different solubilities in DMF of 0.63 mole L⁻¹ (at 21° C.) and 0.76 mole mL⁻¹ (at 21° C.), respectively. During crystallization, as DMF evaporates rapidly from the edges of the triangle, the concentration of CsI crosses the solubility limit first; this may lead to the formation of a Cs-rich phase at the starting point. Closer inspection of the starting point (i.e., the acute angle defined by a mask) by scanning electron microscopy (SEM) indeed showed fused cuboid nanocrystals (see FIGS. 11A-11C), which appear to be physically different from the rest of the area with δ-CsPbI₃ microwires (see FIG. 11D). Energy dispersive X-ray spectroscopy (EDS) analysis showed that the starting point is Cs-rich. FIG. 12A includes EDS data and an SEM image associated with a crystallization starting point and FIG. 12B includes EDS data and an SEM associated with microwires formed away from the starting point. The initial growth was Cs rich but the pXRD pattern of the starting point did not show diffraction peaks from Cs-rich phases such as CsI and Cs₄PbI₆. This may be due to the very small amount of Cs-rich phase present at the starting point.

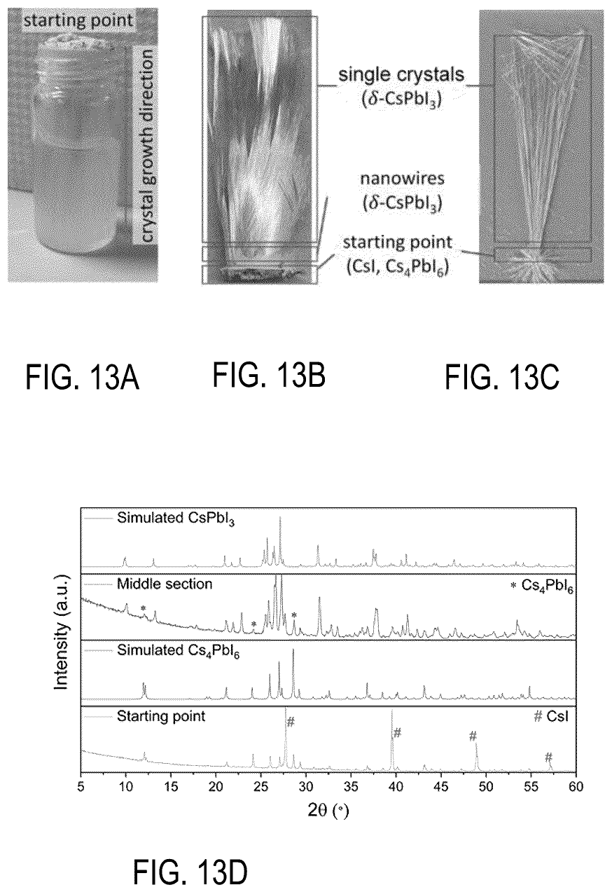

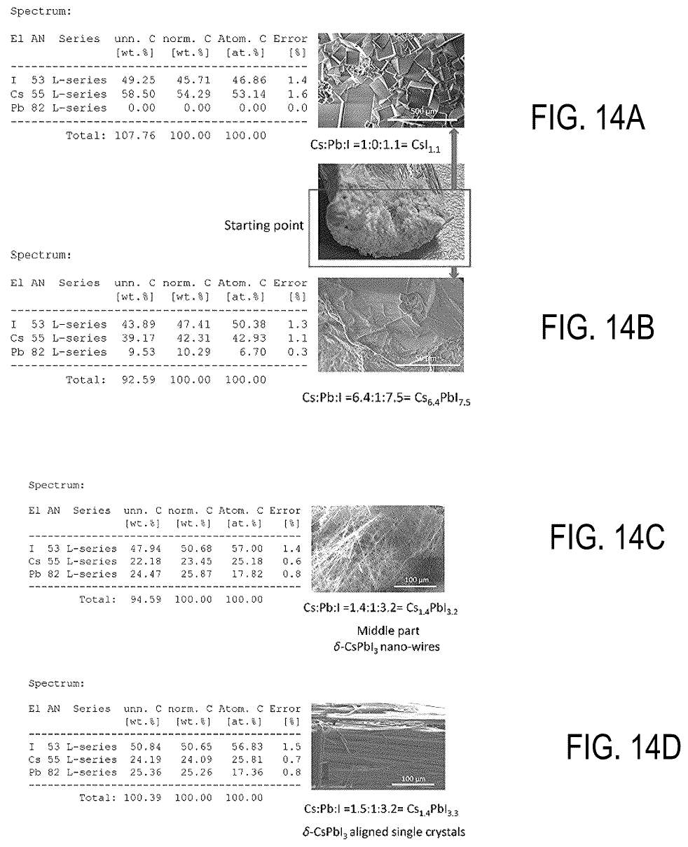

To validate the hypothesis of Cs-rich-phase triggered growth, the process was upscaled in a vial as shown in FIGS. 13A-13C. Similar to the substrate-based crystallization process, vial-based crystallization also starts with formation of seeds at starting points. As shown in FIGS. 13A-13C, the needle-like δ-CsPbI₃ crystals have three regions: a crystalline starting point, a nanowire region, and single crystal δ-CsPbI₃ microwires. Similar to the small-scale substrate-based process discussed above, FIG. 13D shows that a pXRD pattern associated with a starting point matches the diffraction pattern of CsI and Cs₄PbI₆. The high-resolution SEM images show small cubic crystals of CsI at an initial point and becoming suitable δ-CsPbI₃ distant form the initial point (see FIGS. 14A-14D), which is similar what is observed for substrate-based crystallization shown in FIGS. 11A-11D. EDS analysis of the starting point shows CsI and Cs-rich lead halide phase (most likely Cs₄PbI₆). The middle transition region matches mostly with δ-CsPbI₃. The SEM image shows δ-CsPbI₃ nanowires in this region. This observation agrees with the hypothesis that CsI crystallizes first, followed by Cs₄PbI₆ and finally CsPbI₃ crystals.

### Representative δ-CsPbI₃ X-Ray Detectors

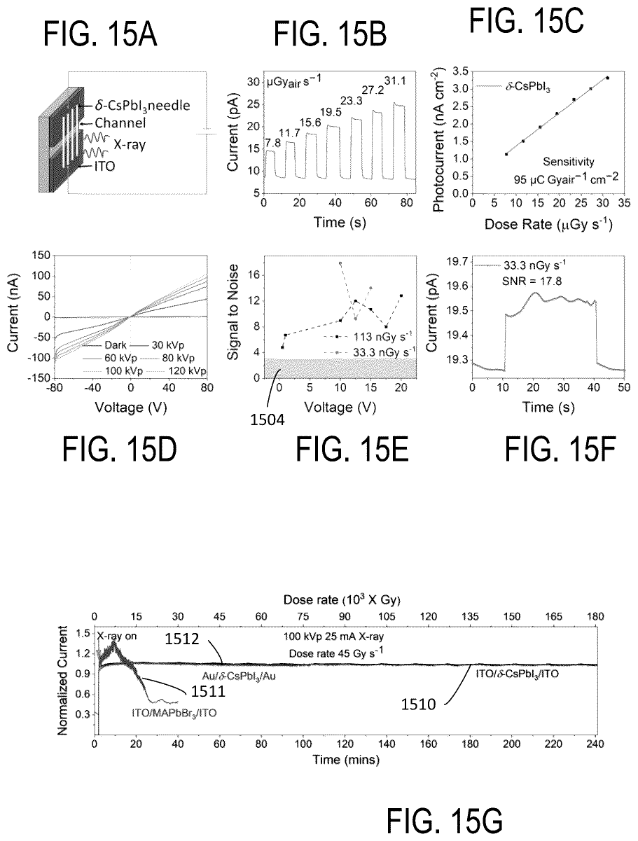

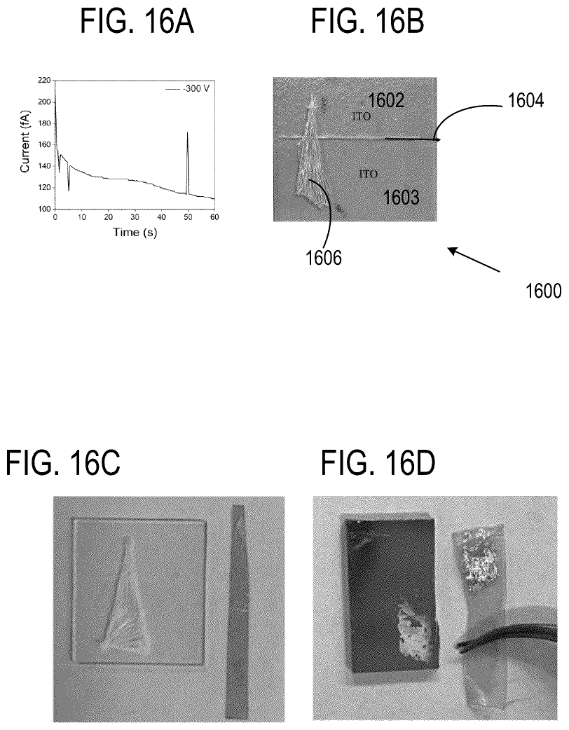

Crystals were grown on a pre-patterned ITO substrate to build an ITO/δ-CsPbI₃/ITO device architecture as shown in FIG. 15A. This architecture was selected because it can produce small active device areas (pixels) required for high-resolution X-ray imaging. In addition, the ITO/δ-CsPbI₃/ITO interface is stable as shown in FIGS. 16C-16D. FIG. 16C shows the adhesion between as-grown CsPbI₃ single crystals on ITO and FIG. 16D shows the adhesion between a vapor deposited silver electrode and a glass substrate. A polyamide tape (adhesion to steel: 25 oz/inch, adhesion type: silicone) was first attached to a respective surface and then pulled by hand to detach from the surface. CsPbI₃ single crystals adhere to the substrate and are not removed by the tape, in contrast to silver electrodes which are damaged.

Characteristics of a representative X-ray detector are illustrated in FIGS. 15B-15G. FIG. 15B shows ON/OFF photocurrent response of such a detector under various dose rates and FIG. 15C shows X-ray generated photocurrent as a function of X-ray dose rate. FIG. 15D show photoconductivity measurement as a function of X-ray energy. FIG. 15E show signal-to-noise ratio of the device derived by calculating the standard deviation of the X-ray photocurrent. A shaded area 1504 represents a signal-to-noise ratio (SNR)<3. The detection limit is thus calculated to be 33.3 nGyₐᵢᵣ s⁻¹. FIG. 15F illustrates ON/OFF response of the device to the lowest detectable X-ray dose rate at 125 V mm⁻¹. The data were smoothed by averaging 10 consecutive data points. FIG. 15G illustrates operational stability of different detectors under continuous exposure to 100 kVp X-rays (45 Gy s⁻¹ dose rate) at an applied bias of 5 V: ITO/d-CsPbI₃/ITO (curve 1510), ITO/MAPbBr₃/ITO (curve 1511), and Au/δ-CsPbI₃/Au (curve 1512).

Low dark current is important for X-ray detectors, as it decreases the noise level and enables the detection of small radiation doses. Dark current is inversely proportional to resistivity. The disclosed devices showed a high bulk resistivity of 2.23×10¹⁴ Ωcm, at least five orders of magnitude higher than previously reported for CsPbI₃ and for 3D halide perovskite crystals. δ-CsPbI₃ has a wide indirect bandgap of 2.67 eV, which in turn decreases the concentration of thermally generated charge carriers. This, in combination with low traps, enables the devices made from δ-CsPbI₃ to achieve an extremely low dark current of 412.5 fA mm⁻² under −3,750 V mm⁻¹ electric field, a value which is twenty-fold lower than that in state-of-art a-Se detectors. FIG. 16A shows dark current as a function of time and FIG. 16B illustrates a representative X-ray detector 1600. The X-ray detector 1600 includes ITO electrodes 1602, 1603, separated by an 80 μm gap 1604. A set of crystals 1606 spans the gap and couples to the ITO electrodes 1602, 1603. For resistivity calculations, crystal dimensions were assumed to be 0.2 cm (a distance parallel to the gap 1604) and a crystal thickness was assumed to be 50 μm.

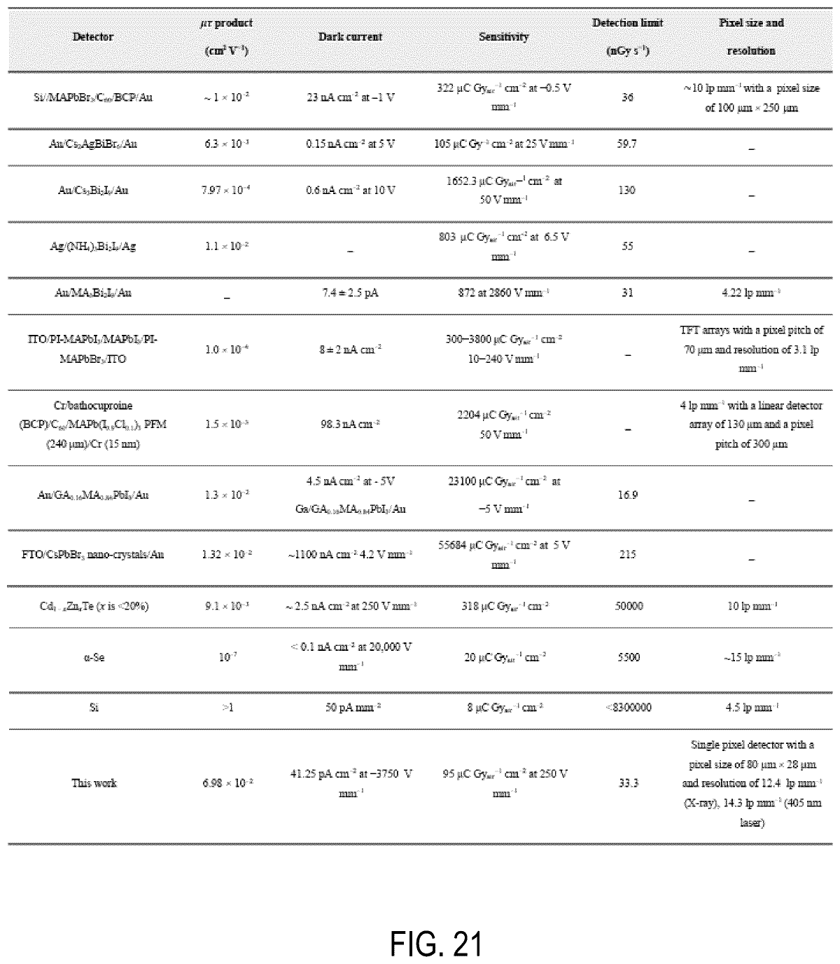

μτ product is another important figure-of-merit for X-ray detectors, as it determines the charge collection efficiency. Using a modified Hecht equation, a μτ product was estimated as 7×10⁻² cm² V⁻¹ (see FIG. 21), the highest reported for metal halides and conventional a-Se and CZT detectors. The δ-CsPbI₃ detector showed an area sensitivity of 95 μC Gyₐᵢᵣ⁻¹ cm⁻² (or volume sensitivity of 19000 μC Gyₐᵢᵣ⁻¹ cm⁻³) under 50 kVp X-ray beam (see FIGS. 15B-15C), five-fold higher than a-Se detectors. The area sensitivity of this example detector is lower than that of recently reported MAPbI₃ devices, but this can be improved by increasing crystal thickness.

To investigate the response of the detectors to different X-ray energies, devices we exposed to various peak intensity X-ray beams as shown in FIG. 15D. As expected, with an increase in X-ray beam energy the photocurrent also increased significantly.

The detection limit is another important figure-of-merit of an X-ray detector. A low detection limit allows the detector to be used in medical imaging at a much lower X-ray dose rate, significantly suppressing the potential risk of radiation damage. The lowest detectable X-ray dose rate was as low as 33.3 nGyₐᵢᵣ s⁻¹ at 125 V mm⁻¹ with an SNR of 17.8 (FIG. 15F), which is much higher than the required SNR of 3. This dose limit is 165 times lower than what is required for regular medical diagnostics (5.5 μGyₐᵢᵣ s⁻). Such a low detection dose may be attributable to the low dark current in the disclosed devices.

### Representative δ-CsPbI₃ X-Ray Columnar Detectors

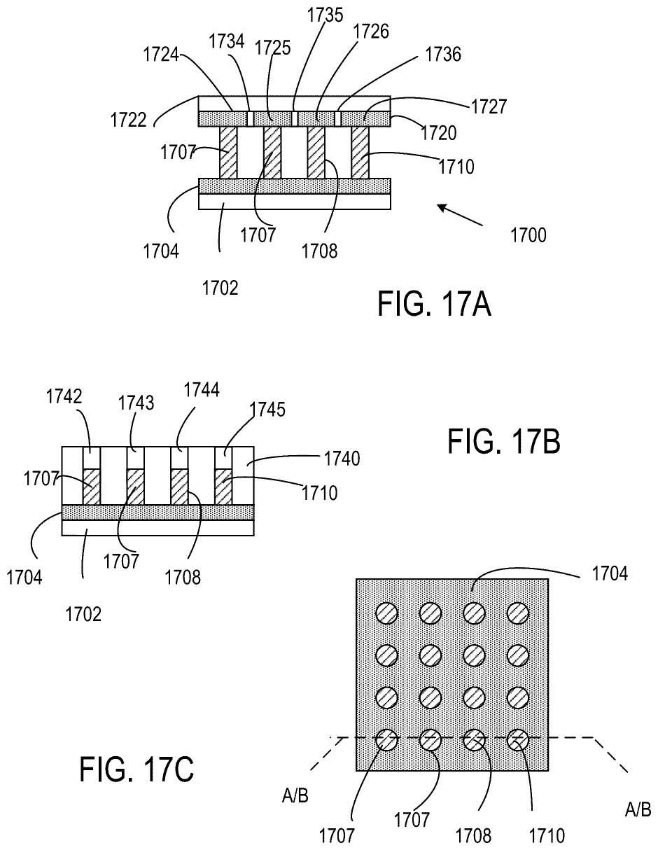

Referring to the sectional view of FIG. 17A, a representative columnar X-ray detector 1700 includes a substrate 1702 having a base conductive layer 1704 that may or may not be patterned to defined detector pixels (i.e., may or may not be pixelated). A surface of the base conductive layer is typically treated as discussed above to promote crystal formation. Microwires 1707-1710 of δ-CsPbI₃ extend from the base conductive layer 1704 to an upper conductive layer 1720 that is provided on a substrate 1722. One of the base conductive layer 1704 and the upper conductive layer 1720 is generally pixelated. As shown, insulating gaps 1734-1736 are situated to define independent electrodes 1724-1727 in the upper conductive layer. Fewer or more δ-CsPbI₃ microwires can be provided. In typical examples, the microwires have diameters of 50 μm to 5 mm and a separation of the upper conductive layer 1720 and the base conductive layer 1704 is typically between 0.1 mm and 25 mm, 1 mm and 10 mm, or 2 mm and 5 mm. In some examples, the separation is between 1.5 mm and 3.0 mm. It is generally desirable that microwires be placed with minimal gaps to avoid dead zones that are not responsive to X-rays.

FIGS. 17B-17C illustrate a representative method of fabrication. As shown in FIG. 17B, wells 1742-1745 are provided in a mold layer 1740 for application of the appropriate crystal growing solution. The microwires 1707-1710 of δ-CsPbI₃ are shown during a growth stage as extending only partially in the respective wells. FIG. 17C is a plan view showing the microwires 1707-1710 of δ-CsPbI₃ situated on the base conductive layer 1704 with the mold layer 1740 removed, prior to application of the upper conductive layer 1720. FIG. 17C also indicates a section line associated with the sectional views of FIGS. 17A-17B.

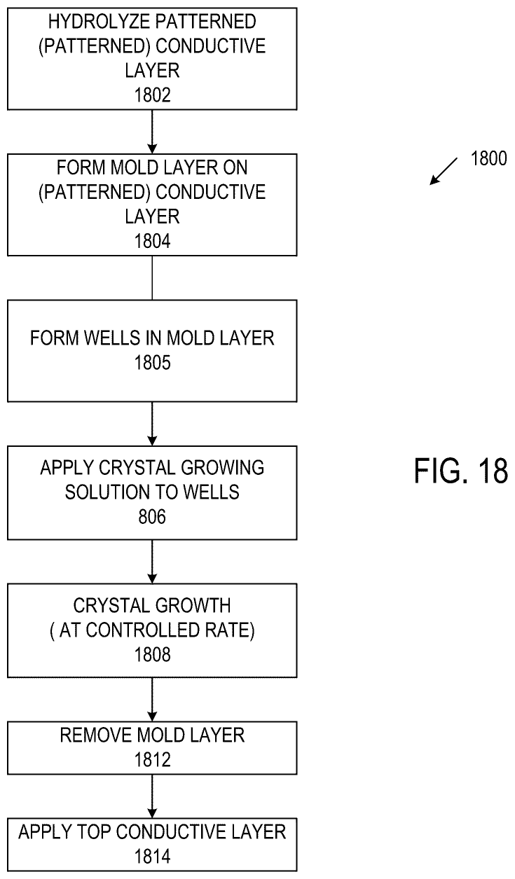

Referring to FIG. 18, a representative method 1800 includes surface treating a conductive layer at 1802, generally to make the surface more hydrophilic. The conductive layer can be patterned or unpatterned. At 1804, a mold layer is formed on the surface-treated conductive layer and at 1805, wells are formed in the mold layer. At 1806, a suitable crystal growing solution is applied to the wells and crystal growth is provided at 1808 with a suitable growth rate. Any of the approaches discussed above can be used to establish a growth rate, if needed or desired. After microwires are grown, the mold layer is removed at 1812, and the upper conductive layer is applied at 1814. One or both of the conductive layers is generally pixelated as convenient. While it is generally preferred that the mold layer is removed, it can be allowed to remain. In the following, such methods and detectors are described with reference to particular materials, but various materials can be used for mold layers, conductive layers, and substrates. Growth in wells is similar to that in vials as described with reference to FIGS. 13A-13B so that after initiation of growth at a base layer, microwires are formed that extend upward, from a base conductive layer to an upper conductive layer.

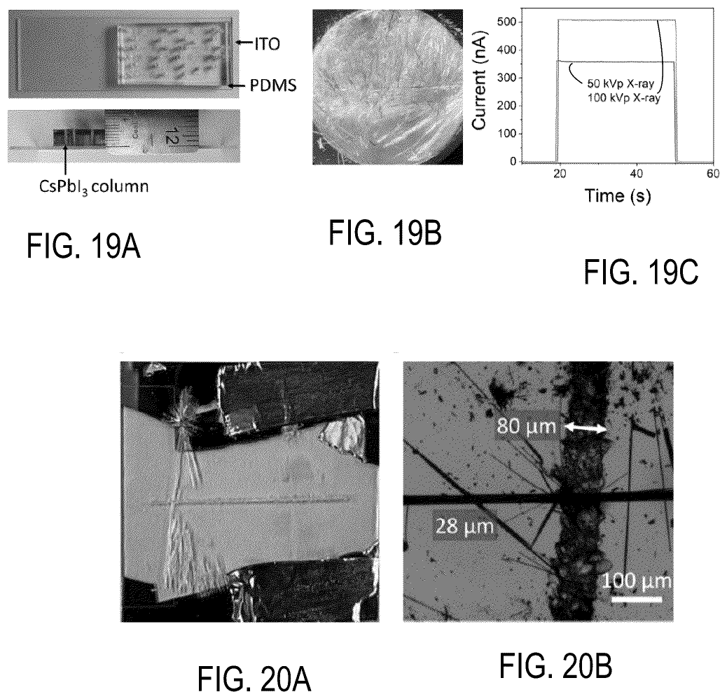

In an example, columnar δ-CsPbI₃ crystals were grown in an 8 mm thick polydimethylsiloxane (PDMS) mold with 0.5 mm diameter vertical channels. FIG. 19A illustrates a PDMS layer bonded to an ITO layer on a glass substrate showing wells that include δ-CsPbI₃ crystals. In FIG. 19A, growth is not yet completed, and crystals are not apparent in all wells. FIG. 19B is a microscope image of as-grown δ-CsPbI₃ crystals viewed from an upper surface of the δ-CsPbI₃ crystal. FIG. 19C is a graph showing an ON/OFF ratio of a columnar δ-CsPbI₃ detector (ITO/δ-CsPbI₃/Au) under 50 kVp and 100 kVp X-ray beam energies. The ON/OFF ratio is about 1000.

### Representative Materials and Methods

### Crystal Growth Solutions

CsI (99.99%), PbI₂ (99%), PbBr₂ (≥98%), and ITO coated PET substrates were purchased from Sigma Aldrich. MABr was purchased from Greatcell Solar. Gold (99.999%) was purchased from Angstrom Engineering. Pre-patterned ITO substrates were purchased from Ossila. DMF was purchased from Fisher Scientific. All chemicals were used without further purification.

### Growth of δ-CsPbI₃ Single Crystals

Centimeter-long δ-CsPbI₃ single crystals with high aspect ratio were grown directly on top of either glass or ITO substrates. First, the substrates were sequentially cleaned with water, acetone, and isopropanol, and dried by nitrogen gas flow. Patterns were made using polyimide masking tape. The substrates were then treated with UV/ozone for 2 hours to modify the surface and to increase the hydrophilicity of the unmasked area. The tape was then removed and a certain amount of the precursor solution (CsI and PbI₂ dissolved in DMF) was dispensed on the treated area. The substrates were left undisturbed for one day, and δ-CsPbI₃ single crystals started to form within an hour. To decrease the rate of solvent evaporation and to improve the crystal size and quality, additional DMF was added inside the crystallization environment.

### X-Ray Detector Fabrication

X-ray detectors were fabricated on pre-patterned 1 inch×1 inch ITO substrates (sheet resistance 20Ω/□). First, an ˜80 μm channel was created by etching the ITO coating with a diamond tip glass cutter. The substrates were cleaned with deionized water, acetone, and isopropanol in an ultrasonication bath, sequentially. For the directional growth of δ-CsPbI₃ single crystals on the etched ITO substrates, the substrates were masked by polyimide tape with fixed dimensions in the shape of a triangle with a ˜15° angle. For the growth of MAPbBr₃ single crystals, a rectangular shape was chosen. The masked substrates were treated with UV/ozone for 2 hours to modify the surface. Immediately after the UV/ozone treatment, precursor solutions were drop-casted on the treated area and left for one day, undisturbed, while crystallization occurred.

The flexible X-ray detectors were fabricated on ITO coated PET substrates (sheet resistance 60Ω/□). Similar to the ITO coated glass substrates, an ˜80 μm channel was created by etching the ITO coating with a steel blade. The PET substrates were cleaned with deionized water and isopropanol in an ultrasonication bath, sequentially. A similar procedure was followed to grow the directional δ-CsPbI₃ single crystals.

To increase the absorption of X-rays, a thicker CsPbI₃ layer was grown. As a proof of concept, an 8 mm thick PDMS mold was fabricated. In order to fabricate the microfluidic channels, first, an SU8 photoresist mold was fabricated in a cleanroom facility. SU8 3050 was spin coated on a silicon wafer at 3000 rpm for 30 s, followed by soft baking at 65° C. and 95° C. Then, the SU8 was exposed to the UV light through a photomask, which was followed by another round of baking at 65° C. and 95° C. The unexposed SU8 was removed by immersing the wafer in a batch of a SU8 developer. Finally, the wafer was hard-baked at 200° C. to enhance the adhesion of the SU8 features to the silicon wafer.

PDMS and its curing agent were mixed in a 10:1 ratio, poured over the SU8 mold, degassed for an hour in a desiccator, and cured overnight in an oven (65° C.). Then the PDMS channel and an ITO plate were washed with soapy reverse osmosis water, rinsed with RO water, isopropyl alcohol, and ethanol. After blow-drying and baking on a hot plate (90° C.), the PDMS channel and ITO plate were plasma treated (Diener Electronic, Zepto ONE) for 38 s, and permanently bonded to each other. The chip was then baked at 80° C. for 2 hours to achieve a perfect bonding. The PDMS mold had ten 0.5 mm size vertical channels, which were connected with microchannels. CsPbI₃ precursor solution (0.65 M in DMF) was injected in the channels. Vertical columns of CsPbI₃ single crystals were grown on ITO by slow evaporation of DMF.

The dark current of the detectors was measured using a PTW UNIDOS E electrometer. A Keithley 617 sourcemeter was used for the measurement of detection limit and to collect current-voltage characteristics. A Comet MXR-160/22 X-ray tube with a focal spot of diameter 5.5 mm was used as an X-ray source. For the current-voltage measurements, the detector to X-ray source distance was 43 mm. To calculate the dose rate, a Monte Carlo simulation was conducted as described in the literature. 47 For the detection limit, a different attenuator was used, made of copper (0.36 mm to 1.44 mm thick). The X-ray dose rate was measured by a PTW Farmer 30001 ionization chamber. The X-ray ON/OFF ratio and dose-dependent X-ray response were measured with a Keithley 4200-SCS semiconductor characterization system and Newton Scientific Model M237 X-ray tube. The X-ray tube voltage was set to 50 kV. The X-ray dose was varied by changing the tube current. The dose rate was carefully calibrated with a Radcal ion chamber (model: 10X6-180) dosimeter. The distance between the device and the X-ray source was set to 71 cm.

pXRD measurements were done on a PANalytical Empyrean system using a Cu (Kα, 1.5406 Å) source. Scanning electron microscopy images were captured with a Hitachi S-4800 FESEM. Optical microscopy images were captured at 1.25× object magnification with a Cytation 5 Cell Imaging Multi-Mode Reader on Brightfield Gen5™ Microplate Reader and Imager Software. Energy dispersive X-ray spectroscopy images were taken on a Bruker Quantax EDS system from Hitachi S-4800 FESEM. An Angel Canada ultrasonic cleaner was used for cleaning the substrates. Hydrophilic treatment of substrates was performed using a high-intensity Ossila UV ozone cleaner.

### Calculation of Sensitivity

The sensitivity of the detector was evaluated based on the ON/OFF photocurrent response under a certain electric field for a 50 kVp X-ray beam. The X-ray dose rate was varied by changing the X-ray tube current. The photocurrent shows a linear relationship with the X-ray dose rate, as plotted in FIG. 15C. The sensitivity of the device at a −250 V/mm electric field was extracted by calculating the slope of the linear fit form of FIG. 4c.

The Z_{eff} was calculated by the following equation:

$${Z}_{eff} = \sqrt[m]{\sum {v}_{i} {Z}_{i}^{m}} \qquad ( 1 )$$

where mᵢ is the fractional number of electrons belonging to the i^{th} material with atomic number Zᵢ and m is a value 3.5.
X-ray sensitivity (S) of the detectors was calculated as

$$S = Δ I / DA \qquad ( 2 )$$

where ΔI is the photocurrent (ΔI=I_{light}−I_{dark}), D is the dose rate of incident X-ray radiation, and A the area of the detector.

### Signal-to-Noise Ratio

Signal-to-noise ratio (SNR) was calculated as:

$$SNR = {I}_{signal} / {I}_{noise} \qquad ( 3 )$$

Signal current (I_{signal}) was calculated by subtracting the average photocurrent (Iphoto) by the average dark current (I_{dark}). The noise current (Iₙₒᵢₛₑ) is the standard deviation of the photocurrent:

$$I = \frac{{I}_{0} μτ V}{{L}^{2}} + \frac{1 - {e}^{( - {L}^{2} / μτ V )}}{1 + \frac{Ls}{V μ}} \qquad ( 4 )$$

### MTF Measurements

The modulation transfer function (MTF) is a mechanism to determine the fundamental spatial resolution of the imaging system by measuring how the input signal is degraded as a function of input signal frequency. The limiting spatial resolution occurs at the spatial frequency when the MTF equals 0.1.

### Experimental MTF

The experimental laser and X-ray MTFs were determined using the edge method. For the laser MTF, a 20 mW, 405 nm laser was used as a source in place of the X-ray tube. For the X-ray MTF, the detector was rotated 900 so that the X-rays would have more material in which to be absorbed while maintaining roughly the same cross-section. A 0.36 mm copper plate was then moved at a speed of 5 μm/s (laser) or 10 μm/s (X-ray) between the source and the detector. This produced an edge profile with respect to time. From the edge profile, the edge spread function (ESF) could be calculated by transforming the edge profile with respect to time to an edge profile with respect to the position of the edge. Then, the line spread function (LSF) could be calculated by differentiating the ESF with respect to the position of the edge. The MTF was calculated by taking the fast Fourier transform (FFT) of the LSF:

$$M T F ( f ) = F F T ( L S F ( x ) ) = F F T ( d E S F ( x ) / dx ) \qquad ( 5 )$$

where f is the spatial frequency and x is the position of the copper edge.

### Simulated MTF

The simulated MTF was calculated by measuring a 1-dimensional point spread function (PSF) of a small X-ray pencil beam. The signal from a 26-μm diameter detector was measured as the X-ray beam was scanned across it in 1 μm increments from −20 μm from the detector to +20 μm from the detector. This produced a natural LSF, from which the FFT was taken to obtain the simulated MTF, as in Equation 5 above.

### Imaging

The X-ray imaging experiments were conducted on a Comet MXR-160/22 X-ray tube with a focal spot of diameter 0.4 mm. The X-ray tube was operated at 40 kVp and 10 mA using no beam filtration. The X-ray beam was shaped by a 3×8 mm² collimator. The source-to-detector distance was 357 mm and the source-to-object distance was 352 mm. For X-ray imaging, the object, fixed on a horizontal scanning stage (Newport Corporation M-IMS600LM), was moved in and out of the beam path in the x direction at multiple y positions to obtain the complete image. The photocurrent of the detector was collected by a Keithley 617 sourcemeter at 50 V bias.

Imaging and Resolution of with a Representative Detector

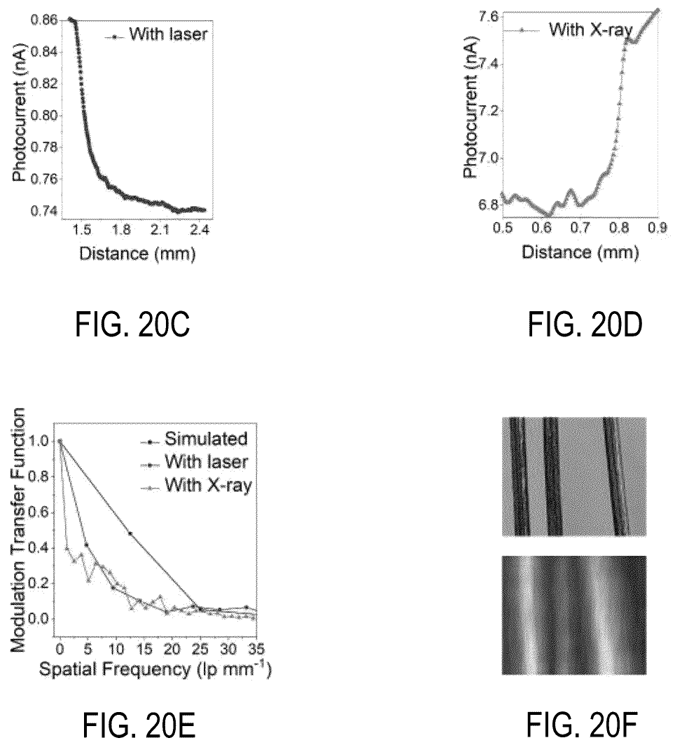

To demonstrate the imaging capability of the disclosed detectors, a single-pixel detector of ˜80 μm×28 μm in area was made by removing all the crystals grown on the ITO-coated substrate except one as shown in FIGS. 20A-20B. This detector was evaluated with the glass slide oriented facing the X-ray tube. This created an active detector area with the thickness of the single crystal that operated only at the point the crystal crossed the channel. When a 0.36 mm thick copper plate was moved in front of the detector to obtain the edge spread function (ESF) shown in FIG. 20D, no discernible difference was seen in the photocurrent. This is likely due to extremely low X-ray attenuation by a single crystal, as well as interference caused by air ionization.

To increase the attenuation within the detector and thus increase the SNR, a full detector with no broken crystals was rotated 90°, so that the edge of the glass slide was perpendicular to the X-ray beam. This orientation increased the effective thickness of the detector; as it would appear as a stack of wires on top of one another, thus increasing X-ray attenuation. The size of the “pixel” would still be similar to the single wire since the thickness of the detector above the glass is only as large as the diameter of the thickest wire and the glass was edge-on to the X-ray beam. Now, all of the wires would be attenuating instead of just a single wire, increasing the signal. The ESF was obtained by moving the copper plate between the source and the detector, leading to a resolution of 12.4 lp/mm (see FIG. 20E).

To evaluate the resolution without the effects of air ionization and non-ideal attenuation, the resolution performance was then measured using a 405 nm laser power source and the single crystal detector. This setup resulted in a modulation transfer function (MTF) with a value of 14.3 lp/mm at 10% MTF (FIG. 20C shows the associated ESF and the MTF is shown in FIG. 20E). Using Monte Carlo methods, we simulated a theoretical resolution of 25 lp/mm at 10% MTF for the detector as also shown in FIG. 20E. To achieve the theoretical value, both the detector and copper plate used to create the ESF should be perfectly perpendicular to the direction of the incident laser or X-ray beam, which can be realized using an automated setup. Nevertheless, our experimental spatial resolution is one of the highest reported so far for X-ray detectors as shown in FIG. 21.

To demonstrate the imaging capability of the CsPbI₃ detectors, a paper clip was imaged optically (top image) and with X-rays (bottom image) as shown in FIG. 20F. The constructed X-ray image of the paper clip shows sharp and well-resolved features.

### REPRESENTATIVE EXAMPLES

Example 1 is a method of growing orthorhombic cesium lead iodide (δ-CsPbI₃) microwires, including drop-casting a solution of CsI and PbI₂ in a solvent onto a patterned substrate; and forming at least one δ-CsPbI₃ microwire by allowing the solvent to evaporate.

Example 2 includes the subject matter of any of Example 1, and further includes situating the drop-casted solution on the patterned substrate in a chamber, wherein the solvent is allowed to evaporate in the chamber.

Example 3 includes the subject matter of any of Examples 1-2, and further includes providing an atmosphere in the chamber that includes a solvent vapor to regulate evaporation of the solvent from the patterned substrate.

Example 4 includes the subject matter of any of Examples 1-3, and further specifies that the patterned substrate is a hydrophilic substrate, and the solvent is N,N-dimethylformamide (DMF).

Example 5 includes the subject matter of any of Examples 1-4, and further specifies that the solvent comprises one or more of N-methyl-2-pyrrolidone (NMP), alkyl-2-pyrrolidone, N,N-dimethylformamide (DMF), dimethylsulfoxide (DMSO), dialkylformamide, γ-butyrolactone (GBL), 2-methylpyrazine (2-MB), 1-pentanol (1-P), 2-methoxyethanol (2-ME), and N, N′-Dimethylpropyleneurea (DMPU).

Example 6 includes the subject matter of any of Examples 1-5, and further specifies that the patterned substrate includes at least one non-conductive channel and the at least one δ-CsPbI₃ microwire is grown to extend in a direction perpendicular to a channel length.

Example 7 includes the subject matter of any of Examples 1-6, further wherein the patterned substrate includes a first electrical contact and a second electrical contact and the at least one δ-CsPbI₃ microwire is grown between the first electrical contact and the second electrical contact.

Example 8 includes the subject matter of any of Examples 1-7, and further specifies that the patterned substrate is insulating and the first electrical contact and the second electrical contact are situated on a surface of the patterned substrate.

Example 9 includes the subject matter of any of Examples 1-8, and further specifies that the first electrical contact and the second electrical contact are metals or ITO.

Example 10 includes the subject matter of any of Examples 1-9, and further specifies that the patterned substrate includes a plurality of first electrical contacts and a corresponding plurality of second electrical contacts and forming the at least one δ-CsPbI₃ microwire includes forming a plurality of δ-CsPbI₃ microwires so that each of the first electrical contacts is coupled to a corresponding second electrical contact by respective δ-CsPbI₃ microwire.

Example 11 includes the subject matter of any of Examples 1-10, and further specifies that the patterned substrate includes a plurality of non-conductive channels situated so that a non-conductive channel separates each δ-CsPbI₃ microwire from adjacent δ-CsPbI₃ microwires, wherein each non-conductive channel as a width for between 1 μm and 1 mm.

Example 12 includes the subject matter of any of Examples 1-11, and further specifies that the at least one δ-CsPbI₃ microwire extends along a crystalline [100] axis.

Example 13 includes the subject matter of any of Examples 1-12, whether the patterned substrate defines an acute angle so that formation of the at least one δ-CsPbI₃ microwire is initiated at the acute angle.

Example 14 includes the subject matter of any of Examples 1-13, and further specifies that the acute angle is between 5 and 75 degrees, Example 7.5 and 60 degrees, or 10 and 45 degrees.

Example 15 includes the subject matter of any of Examples 1-14, and further specifies that the acute angle is defined by a mask applied to the patterned substrate or patterning formed in a conductive layer on a surface of the patterned substrate.

Example 16 includes the subject matter of any of Examples 1-15, and further specifies that a composition of the at least one δ-CsPbI₃ microwire includes a seed region that is Cs-rich proximate the acute angle.

Example 17 is an X-ray detector, including: a first conductor and a second conductor; and at least one orthorhombic cesium lead iodide (δ-CsPbI₃) microwire extending from the first conductor to the second conductor and electrically coupled to the first conductor and the second conductor proximate respective ends of the at least one δ-CsPbI₃ microwire.

Example 18 includes the subject matter of Example 18, and further specifies that the first conductor and the second conductor are metals.

Example 19 includes the subject matter of any of Examples 17-18, and further specifies that the first conductor and the second conductor are indium tin oxide (ITO).

Example 20 includes the subject matter of any of Examples 17-19 and further includes an insulating substrate, wherein the first conductor and the second conductor are situated on a surface of the insulating substrate.

Example 21 includes the subject matter of any of Examples 17-20, and further specifies that the at least one δ-CsPbI₃ microwire comprises a plurality of δ-CsPbI₃ microwires extending to the first and second conductors.

Example 22 includes the subject matter of any of Examples 17-21, and further specifies that each of the first and second conductors includes multiple electrically isolated contact regions corresponding to the plurality of δ-CsPbI₃ microwires.

Example 23 includes the subject matter of any of Examples 17-22, and further specifies that the insulating substrate includes a plurality of grooves and each of the δ-CsPbI₃ microwires is situated between a pair of the grooves.

Example 24 includes the subject matter of any of Examples 17-23, and further specifies that the at least one δ-CsPbI₃ microwire has a length of at least 5 mm, 1 cm. Example 1.5 cm, Example 2.0 cm, Example 3.0 cm, Example 4.0 cm, or Example 5.0 cm.

Example 25 includes the subject matter of any of Examples 17-24, and further specifies that the at least one δ-CsPbI₃ microwire has an effective diameter of between 1 μm and 1 mm or between 10 μm and 100 μm.

Example 26 includes the subject matter of any of Examples 17-25, and further specifies that the at least one δ-CsPbI₃ microwire has a resistivity of at least 1×10¹⁴ Ωcm.

Example 27 includes the subject matter of any of Examples 17-26, and further specifies that the at least one δ-CsPbI₃ microwire has a resistivity of at least 1×10¹³ Ωcm, 1×10¹² Ωcm, or 1×10¹¹ Ωcm.

Example 28 includes the subject matter of any of Examples 17-27, and further specifies that the at least one δ-CsPbI₃ microwire has a mobility-lifetime (μτ) product of at least 1×10⁻² cm² V⁻¹ or 1×10⁻¹ cm² V⁻¹.

Example 29 includes the subject matter of any of Examples 17-28, and further specifies that the at least one δ-CsPbI₃ microwire is electrically coupled to the first conductor and the second conductor with respective Schottky barriers.

Example 30 includes the subject matter of any of Examples 17-29, and further specifies that the insulating substrate is a rigid or flexible substrate.

Example 31 is an X-ray detector, including: a base substrate; an upper substrate; and a plurality of δ-CsPbI₃ microwires extending from the base substrate to the upper substrate.

Example 32 includes the subject matter of Example 31, and further specifies that the base substrate includes a base conductive layer and the upper substrate includes an upper conductive layer, wherein each of the plurality of δ-CsPbI₃ microwires extends from the base conductive layer to the upper conductive layer.

Example 33 includes the subject matter of any of Examples 31-32, and further specifies that the base substrate and the upper substrate are parallel to each other and have a separation of between 1 mm and 10 mm.

Example 34 includes the subject matter of any of Examples 31-33, and further specifies that a diameter of the δ-CsPbI₃ microwires is between Example 0.5 mm and Example 2.0 mm.

Example 35 includes the subject matter of any of Examples 31-34, and further specifies that at least one of the base substrate and the upper substrate is a flexible substrate.

Example 36 includes the subject matter of any of Examples 31-35, and further specifies that at least one of the base conductive layer and the upper conductive layer is a patterned layer that defines a set of electrodes, wherein each electrode is connected to selected δ-CsPbI₃ microwires.

Example 37 includes the subject matter of any of Examples 31-36, and further specifies that at least one of the base conductive layer and the upper conductive layer is a patterned layer that defined a set of electrodes, wherein each electrode is connected to a selected δ-CsPbI₃ microwire.

Example 38 is a method, including: growing δ-CsPbI₃ microwires in a plurality of wells so that a first end of each extends to a base conductive layer; and contacting second ends of each of the δ-CsPbI₃ microwires to an upper conductive layer.

Example 39 includes the subject matter of Example 38, and further includes forming a mold layer on the base conductive layer and defining wells in the mold layer that extend to the base conductive layer, where the δ-CsPbI₃ microwires are grown in the wells.

Example 40 includes the subject matter of any of Examples 38-39, and further includes removing the mold layer prior to contacting the second ends of the δ-CsPbI₃ microwires with the upper conductive layer.

Example 41 includes the subject matter of any of Examples 38-40, and further includes exposing the wells to a solution, wherein the CsPbI₃ microwires are grown by evaporation of the solution.

### Terminology

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or devices are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

The term “microwire” is used to refer to δ-CsPbI₃ crystals as discussed above. It will be understood that some portions (typically an initiation point for crystal growth) may have compositions that are somewhat different.

In view of the many possible embodiments to which the principles of the disclosed technology may be applied, it should be recognized that the illustrated embodiments are only preferred examples and should not be taken as limiting the scope of the disclosure. We claim as our invention all that comes within the scope and spirit of the appended claims.

We claim:

1. A method of growing orthorhombic cesium lead iodide (δ-CsPbI₃) microwires, comprising:
drop-casting a solution of CsI and PbI₂ in a solvent onto a patterned substrate; and
forming at least one δ-CsPbI₃ microwire by allowing the solvent to evaporate.

2. The method of claim 1, further comprising situating the drop-casted solution on the patterned substrate in a chamber, wherein the solvent is allowed to evaporate in the chamber.

3. The method of claim 2, further comprising providing an atmosphere in the chamber that includes a solvent vapor to regulate evaporation of the solvent from the patterned substrate.

4. The method of claim 1, wherein the patterned substrate is a hydrophilic substrate and the solvent is N,N-dimethylformamide (DMF).

5. The method of claim 1, wherein the solvent comprises one or more of N-methyl-2-pyrrolidone (NMP), alkyl-2-pyrrolidone, N,N-dimethylformamide (DMF), dimethylsulfoxide (DMSO), dialkylformamide, γ-butyrolactone (GBL), 2-methylpyrazine (2-MB), 1-pentanol (1-P), 2-methoxyethanol (2-ME), and N, N′-Dimethylpropyleneurea (DMPU).

6. The method of claim 1, wherein the patterned substrate includes at least one non-conductive channel and the at least one δ-CsPbI₃ microwire is grown to extend in a direction perpendicular to a channel length.

7. The method of claim 1, further wherein the patterned substrate includes a first electrical contact and a second electrical contact and the at least one δ-CsPbI₃ microwire is grown between the first electrical contact and the second electrical contact.

8. The method of claim 7, wherein the patterned substrate is insulating and the first electrical contact and the second electrical contact are situated on a surface of the patterned substrate.

9. The method of claim 8, wherein the first electrical contact and the second electrical contact are metals or ITO.

10. The method of claim 1, wherein the patterned substrate includes a plurality of first electrical contacts and a corresponding plurality of second electrical contacts and forming the at least one δ-CsPbI₃ microwire includes forming a plurality of δ-CsPbI₃ microwires so that each of the first electrical contacts is coupled to a corresponding second electrical contact by respective δ-CsPbI₃ microwire.

11. The method of claim 10, wherein the patterned substrate includes a plurality of non-conductive channels situated so that a non-conductive channel separates each δ-CsPbI₃ microwire from adjacent δ-CsPbI₃ microwires, wherein each non-conductive channel as a width for between 1 μm and 1 mm.

12. The method of claim 1, wherein the at least one δ-CsPbI₃ microwire extends along a crystalline [100] axis.

13. The method of claim 1, whether the patterned substrate defines an acute angle so that formation of the at least one δ-CsPbI₃ microwire is initiated at the acute angle.

14. The method of claim 13, wherein the acute angle is between 5 and 75 degrees, 7.5 and 60 degrees, or 10 and 45 degrees.

15. The method of claim 13, wherein the acute angle is defined by a mask applied to the patterned substrate or patterning formed in a conductive layer on a surface of the patterned substrate.

16. The method of claim 14, wherein a composition of the at least one δ-CsPbI₃ microwire includes a seed region that is Cs-rich proximate the acute angle.

17. An X-ray detector, comprising:
a first conductor and a second conductor; and
at least one orthorhombic cesium lead iodide (δ-CsPbI₃) microwire extending from the first conductor to the second conductor and electrically coupled to the first conductor and the second conductor proximate respective ends of the at least one δ-CsPbI₃ microwire.

18. The X-ray detector of claim 17, wherein the first conductor and the second conductor are metals.

19. The X-ray detector of claim 17, wherein the first conductor and the second conductor are indium tin oxide (ITO).

20. The X-ray detector of claim 17, further comprising an insulating substrate, wherein the first conductor and the second conductor are situated on a surface of the insulating substrate.

21. The X-ray detector of claim 17, wherein the at least one δ-CsPbI₃ microwire comprises a plurality of δ-CsPbI₃ microwires extending to the first and second conductors.

22. The X-ray detector of claim 21, wherein each of the first and second conductors includes multiple electrically isolated contact regions corresponding to the plurality of δ-CsPbI₃ microwires.

23. The X-ray detector of claim 20, wherein the insulating substrate includes a plurality of grooves and each of the δ-CsPbI₃ microwires is situated between a pair of the grooves.

24. The X-ray detector of claim 17, wherein the at least one δ-CsPbI₃ microwire has a length of at least 5 mm, 1 cm, 1.5 cm, 2.0 cm, 3.0 cm, 4.0 cm, or 5.0 cm.

25. The X-ray detector of claim 17, wherein the at least one δ-CsPbI₃ microwire has an effective diameter of between 1 μm and 1 mm or between 10 μm and 100 μm.

26. The X-ray detector of claim 17, wherein the at least one δ-CsPbI₃ microwire has a resistivity of at least 1×10¹⁴ Ωcm.

27. The X-ray detector of claim 17, wherein the at least one δ-CsPbI₃ microwire has a resistivity of at least 1×10¹³ Ωcm, 1×10¹² Ωcm, or 1×10¹¹ Ωcm.

28. The X-ray detector of claim 17, wherein the at least one δ-CsPbI₃ microwire has a mobility-lifetime (μτ) product of at least 1×10⁻² cm² V⁻¹ or 1×10⁻¹ cm² V⁻¹.

29. The X-ray detector of claim 17, wherein the at least one δ-CsPbI₃ microwire is electrically coupled to the first conductor and the second conductor with respective Schottky barriers.

30. The X-ray detector of claim 20, wherein the insulating substrate is a rigid or flexible substrate.

31. An X-ray detector, comprising:
a base substrate;
an upper substrate; and
a plurality of δ-CsPbI₃ microwires extending from the base substrate to the upper substrate.

32. The X-ray detector of claim 31, wherein the base substrate includes a base conductive layer and the upper substrate includes an upper conductive layer, wherein each of the plurality of δ-CsPbI₃ microwires extends from the base conductive layer to the upper conductive layer.

33. The X-ray detector of claim 31, wherein the base substrate and the upper substrate are parallel to each other and have a separation of between 1 mm and 10 mm.

34. The X-ray detector of claim 33, wherein a diameter of the δ-CsPbI₃ microwires is between 0.5 mm and 2.0 mm.

35. The X-ray detector of claim 31, wherein at least one of the base substrate and the upper substrate is a flexible substrate.

36. The X-ray detector of claim 32, wherein at least one of the base conductive layer and the upper conductive layer is a patterned layer that defines a set of electrodes, wherein each electrode is connected to selected δ-CsPbI₃ microwires.

37. The X-ray detector of claim 32, wherein at least one of the base conductive layer and the upper conductive layer is a patterned layer that defined a set of electrodes, wherein each electrode is connected to a selected δ-CsPbI₃ microwire.

38. A method, comprising:
growing δ-CsPbI₃ microwires in a plurality of wells so that a first end of each extends to a base conductive layer; and
contacting second ends of each of the δ-CsPbI₃ microwires to an upper conductive layer.

39. The method of claim 38, further comprising forming a mold layer on the base conductive layer and defining wells in the mold layer that extend to the base conductive layer, where the δ-CsPbI₃ microwires are grown in the wells.

40. The method of claim 39, further comprising removing the mold layer prior to contacting the second ends of the δ-CsPbI₃ microwires with the upper conductive layer.

41. The method of claim 39, further comprising exposing the wells to a solution, wherein the CsPbI₃ microwires are grown by evaporation of the solution.
